(19) United States
(12) Patent Application Publication
(10) Pub. No.: US 2009/0015271 A1
(43) Pub. Date: Jan. 15, 2009

(54) Sensors

(75) Inventor: Howard Elliott, Oxfordshire (GB)

Correspondence Address: GREENSFELDER HEMKER & GALE PC, SUITE 2000, 10 SOUTH BROADWAY, ST LOUIS, MO, 63102, US

(73) Assignee: Future Technology (Sensors) Limited, Banbury (GB)

(21) Appl. No.: 12/217,231

(22) Filed: Jul. 2, 2008

Related U.S. Application Data
(63) Continuation-in-part of application No. 10/573,695, filed on Jun. 27, 2006, now Pat. No. 7,414,415.

(30) Foreign Application Priority Data
Sep. 27, 2003 (GB) 0322655.2

(51) Int. Cl. G01R 27/26

(52) U.S. Cl. 324/690

(57) ABSTRACT

The invention provides a sensor (1) having an electrode (2) that capacitively couples with the object and can be formed from an electrically conductive ceramic material. The electrode (2) is substantially surrounded by a housing (4) formed from an electrically non-conductive ceramic. A first electrically conductive bridge (5) is connected to the electrode (2) and connectable to a first conductor of a transmission cable. A second electrically conductive bridge (7) is connected to the housing (4) and connectable to a second conductor of the transmission cable. The electrically conductive bridges (5,7) extend away from the front face of the electrode (i.e. the face that faces toward the object in use) so that the connection between the conductors of the transmission cable and the electrically conductive bridges takes place at a low temperature region at the rear of the sensor.

### CROSS-REFERENCE TO RELATED APPLICATION

This is a continuation-in-part (CIP) of allowed application Ser. No. 10/573,695, filed 27 Jun. 2006, and entirety of which is herein incorporated by reference, said application Ser. No. 10/573,695 having been the United States national phase of PCT international application PCT/GB2004/003020 having a filing date of 12 Jul. 2004, which claimed the priority of Great Britain patent application 0322655.2 having a filing date of 27 Sep. 2003, and the present application claims the priority of application Ser. No. 10/573,695 and each of the above prior applications.

### TECHNICAL FIELD

The present invention relates to sensors, and in particular to sensors that can be used for capacitively measuring the distance to either a stationary or passing object. The sensors may be capacitive sensors or charge transfer sensors.

### BACKGROUND ART

In many industrial measurement applications there is a need for a sensor that can be used at high operating temperatures to measure the distance to either a stationary or passing object. A typical application is the measurement of clearance between the tip of a gas turbine engine blade and the surrounding casing. In this situation the operating temperature of the sensor can reach 1500° C. Other applications including molten metal and molten glass level measurement, for example, have similar operating temperature requirements.

U.S. Pat. No. 5,760,593 (BICC plc) describes a conventional sensor having a metal or metal-coated ceramic electrode that couples capacitively with the stationary or passing object. The electrode is connected directly to the centre conductor of a standard triaxial transmission cable and is surrounded by a metal shield and an outer housing. The metal shield and the outer housing are connected directly to the intermediate conductor and the outer conductor of the triaxial transmission cable respectively. Electrical insulation is provided between the electrode and the shield and also between the shield and the housing. The insulation can be in the form of machined ceramic spacers or deposited ceramic layers.

One problem with these conventional sensors is that they utilise an alternating combination of metal and ceramic materials. As the operating temperature of the sensor increases, the metal components tend to expand more than the ceramic components. This often results in stress fractures forming in the ceramic spacers or layers, which reduce their electrical performance and may even result in the disintegration or de-lamination of the ceramic components. Not only does this cause the sensor to fail electrically, but the disintegration or de-lamination of the ceramic components also allows the metal components to vibrate and this can result in the mechanical failure of the complete sensor assembly.

Gas turbine engine manufacturers now require an operating lifetime of at least 20,000 hours for sensors that are to be fitted to production models. Although conventional sensors have been successfully used at high operating temperatures for short periods of time, it is unlikely that they will ever be able to meet the required operating lifetime because of the inherent weakness of the sensor assembly caused by the different thermal expansion properties of the metal and ceramic components.

A further problem is the way in which the electrode, shield and outer housing are connected to the transmission cable. With conventional sensor designs, the conductors of the transmission cable are directly connected to the electrode, shield and outer housing at a high temperature region (i.e. a part of the sensor that reaches an elevated temperature in use). Many types of transmission cables cannot be used at high temperatures and often fail after a short period of time. Furthermore, some conventional sensors are not hermetically sealed which allows moisture to penetrate the sensor assembly and its associated transmission cable, thus reducing the performance of the sensor.

### SUMMARY OF THE INVENTION

The present invention provides a sensor for measuring the distance to a stationary or passing object, comprising an electrode for capacitively coupling with the object, and a housing that substantially surrounds the electrode, a first electrically conductive bridge connected to the electrode and connectable to a first conductor of a transmission cable, and a second electrically conductive bridge connected to the housing and connectable to a second conductor of the transmission cable.

The electrode can be formed from an electrically conductive ceramic so that the sensor can be used at higher operating temperatures than conventional sensors that use metal or metal-coated ceramic electrodes. The housing is preferably formed from an electrically non-conductive ceramic and may be of any suitable shape or size to suit the installation requirements.

To isolate the electrode from any external electrical interference, the sensor can further comprise a shield that substantially surrounds the electrode and is electrically isolated from the electrode by an insulating layer. The shield can be formed from a solid piece of electrically conductive ceramic. However, the shield can also be a thin electrically conductive ceramic layer that is deposited onto the insulating layer using conventional deposition techniques. The use of a deposited ceramic layer greatly simplifies both the design of the sensor and subsequent assembly. The shield can also be a thin electrically conductive ceramic or metallic layer that is deposited onto the inside surface of the outer housing using conventional deposition techniques. The insulating layer is preferably formed as a machined electrically non-conductive ceramic spacer. The use of a ceramic layer with a similar coefficient of thermal expansion to both the insulating layer and the housing means that the coating will not tend to delaminate in service, which is possible with metallic coatings which have different thermal expansion characteristics.

Any electrically conductive ceramic and non-electrically conductive ceramic materials used in the sensor assembly are preferably selected to have similar thermal expansion coefficients so that the sensor assembly remains virtually stress free at high operating temperatures. The electrode and the shield can be formed from SiC and the insulating layer and the housing can be formed from SiN, for example. The electrode, shield and housing can be bonded (i.e. joined or connected) together using standard diffusion bonding, sintering or brazing methods to form an integral ceramic structure. The bonding provides a hermetic seal between the components that prevents the ingress of moisture into the sensor assembly and the transmission cable.

The sensor can have a “captive” design so that if any of the ceramic components do fail for any reason then they are retained within the overall sensor assembly.

Instead of joining the conductors of the transmission cable directly to the electrode and the housing at a high temperature region of the sensor, the conductors are preferably connected to electrically conductive bridges that are in turn connected to the electrode and the housing. The electrically conductive bridges may extend away from the front face of the electrode (i.e. the face that faces toward the object in use) so that the connection between the conductors and the electrically conductive bridges takes place at a low temperature region at the rear of the sensor.

If the sensor does not include a shield then a coaxial transmission cable having a first (central) conductor and a second (outer) conductor can be used. The first conductor is connected to the electrode by means of a first electrically conductive bridge and the second conductor is connected to the housing by means of a second electrically conductive bridge. The first electrically conductive bridge may pass through apertures provided in the housing and the second electrically conductive bridge. Other arrangements for the first and second electrically conductive bridges are possible.

The connection between the conductors and the electrically conductive bridges can be made using an adapter. The adapter can be shaped to accommodate a variety of different types and diameters of transmission cable. Furthermore, the adapter can connect the conductors to the electrically conductive bridges in a number of different orientations depending on the installation requirements of the sensor. For example, the conductors can be connected such that the transmission cable extends away from the front face of the electrode substantially parallel to the electrically conductive bridges. Alternatively, the conductors can be connected such that the transmission cable extends substantially at right angles to the electrically conductive bridges. Other orientations are also possible.

If the sensor does include a shield then a triaxial transmission cable having a first (central) conductor, a second (outer) conductor, and a third (intermediate) conductor can be used. The first conductor is preferably connected to the electrode by means of a first electrically conductive bridge, the second conductor is preferably connected to the housing by means of a second electrically conductive bridge and the third conductor is preferably connected to the shield by means of a third electrically conductive bridge. The first electrically conductive bridge may pass through apertures provided in the insulating layer, the shield, the third electrically conductive bridge, the housing and the second electrically conductive bridge. Similarly, the third electrically conductive bridge may pass through aperture provided in the housing and the second electrically conductive bridge. Other arrangements for the first, second and third electrically conductive bridges are possible.

The electrically conductive bridges can be formed from metal or electrically conductive ceramic and are preferably bonded (i.e. joined or connected) to the electrode, housing and shield using standard diffusion bonding, sintering or brazing methods. Although it is generally preferred that the bridges are formed from electrically conductive ceramic, metal bridges can be used because they are connected to the electrode, shield and housing at an intermediate temperature region and so do not suffer significantly from the problems of thermal expansion. The electrically conductive bridges can be made in any size or shape depending on the design and installation requirements of the sensor.

An adapter can be provided to connect the second and third electrically conductive bridges to the outer and intermediate conductors, as described above.

The second electrically conductive bridge can substantially surround the housing such that it extends a part or all of the way along the side face of the housing. However, it is generally preferred that the shield, the insulating layer, the housing and the second electrically conductive bridge do not extend along the front face of the electrode.

The use of electrically conductive bridges means that the sensor assembly can be manufactured and tested before it is connected to the transmission cable using an adaptor. This is not possible with conventional sensors where the transmission cable has to be directly connected to the electrode, housing and shield during the assembly process.

The electrically conductive bridges can also be used with conventional sensors and those that utilise metal/ceramic and plastics/metal components, or any combination of materials thereof.

### DRAWINGS

FIG. 1 is a cross-section view of a sensor according to a first embodiment of the present invention;

FIG. 2 is a cross-section view showing how the sensor of FIG. 1 can be connected to a coaxial transmission cable in a first orientation;

FIG. 3 is a cross-section view showing how the sensor of FIG. 1 can be connected to a coaxial transmission cable in a second orientation;

FIGS. 4a and 4b are cross-section views showing how the first electrically conductive bridge can be adapted to substantially surround the housing of the sensor of FIG. 1;

FIG. 5 is a cross-section view of a sensor according to a second embodiment of the present invention;

FIG. 5a is a cross-section view of a sensor according to a third embodiment of the present invention;

FIG. 5b is a cross-section view of a sensor according to a fourth embodiment of the present invention;

FIG. 6 is a cross-section view showing how the sensor of FIG. 5 can be connected to a triaxial transmission cable in a first orientation;

FIG. 7 is a cross-section view showing how the sensor of FIG. 5 can be connected to a triaxial transmission cable in a second orientation;

FIG. 8 is a cross-section view of a sensor according to a fifth embodiment of the present invention;

FIG. 9 is a cross-section view showing how the sensor of FIG. 8 can be connected to a coaxial transmission cable in a first orientation;

FIG. 10 is a cross-section view showing how the sensor of FIG. 8 can be connected to a coaxial transmission cable in a second orientation;

FIG. 11 is a cross-section view showing how the sensor of FIG. 8 can be connected to a coaxial transmission cable without using an adapter;

FIG. 12 is a cross-section view of a sensor according to a sixth embodiment of the present invention;

FIG. 13 is a cross-section view showing how the sensor of FIG. 12 can be connected to a triaxial transmission cable in a first orientation;

FIG. 14 is a cross-section view showing how the sensor of FIG. 12 can be connected to a triaxial transmission cable in a second orientation; and

FIG. 15 is a cross-section view showing how the sensor of FIG. 12 can be connected to a triaxial transmission cable without using an adapter.

### DESCRIPTION WITH REFERENCE TO DRAWINGS

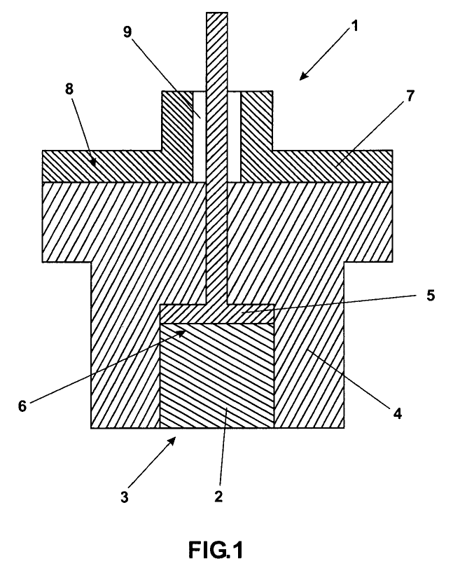

With reference to FIG. 1, a “coaxial” sensor 1 has a cylindrical electrode 2 formed from an electrically conductive ceramic material. A front face 3 of the electrode 2 is directed toward a stationary or passing object (not shown). The electrode 2 is located within and bonded (e.g. diffusion bonded, sintered or brazed) to a housing 4 formed from an electrically non-conductive ceramic material. The electrically conductive and electrically non-conductive ceramic materials are chosen so that they have a similar thermal expansion coefficient and the sensor 1 remains virtually stress free at high operating temperatures.

An inner bridge piece 5 is located within the housing 4 and is bonded to a rear face 6 of the electrode 2. An outer bridge piece 7 is bonded to a rear face 8 of the housing 4. The inner bridge piece 5 passes through apertures provided in the housing 4 and the outer bridge piece 7 to extend beyond the outer bridge piece. The aperture provided in the outer bridge piece 7 is wider than the inner bridge piece 5 so that the two bridge pieces are separated by an annular air gap 9.

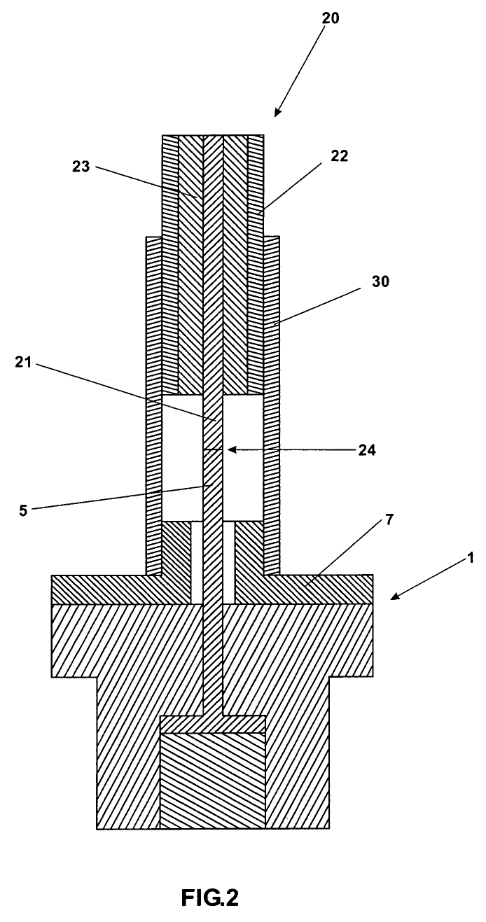

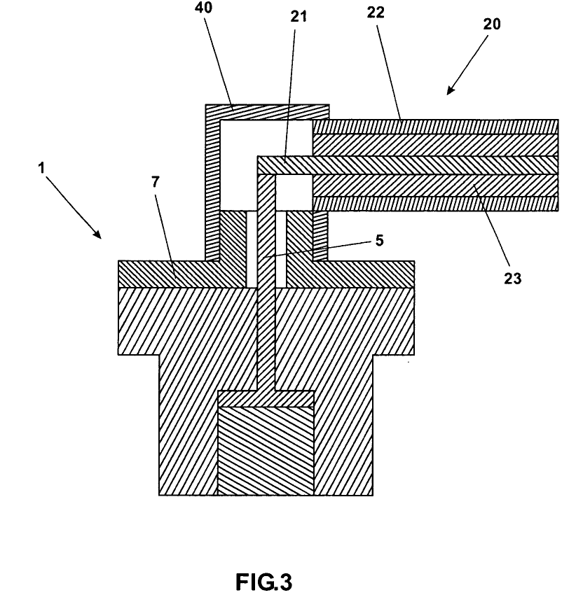

The inner and outer bridge pieces 5 and 7 are connected to the two concentric conductors of a mineral insulated coaxial transmission cable 20 as shown in FIG. 2. The transmission cable 20 has a central conductor 21 and an outer conductor 22 separated by a mineral insulating layer 23. An electrically conductive cylindrical adaptor 30 is used to join the inner bridge piece 5 to the central conductor 21 at a common interface 24 and the outer bridge piece 7 to the outer conductor 22. Alternatively, the electrically conductive adaptor 40 shown in FIG. 3 can be used. The adaptor 40 is designed to receive the transmission cable 20 such that central and outer conductors 21 and 22 are connected substantially at right angles to the inner and outer bridge pieces 5 and 7 and the centreline of the sensor 1.

It will be readily appreciated that the use of the adaptor 30, 40 means that the “coaxial” sensor 1 can be fully assembled and tested before being connected to the transmission cable 20. It also means that the inner and outer bridge pieces 5 and 7 and the central and outer conductors 21 and 22 are connected together at a low-temperature region of the sensor 1.

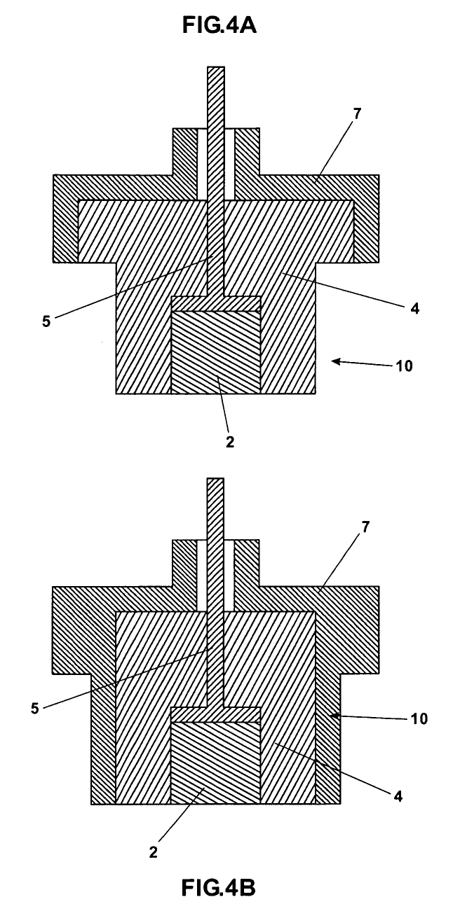

In FIGS. 1 to 3, the outer bridge piece 7 is formed on the rear face 8 of the housing 4 only. However, the outer bridge piece 7 can also extend along part or all of the side face 10 of the housing 4 as shown in FIGS. 4a and 4b.

In operation, the “coaxial” sensor 1 is mounted so that the front face 3 of the electrode 2 is directed toward the stationary or passing object. The electrode 2 is energised by a signal transmitted along the central conductor 21 of the transmission cable 20 so that it capacitively couples with the stationary or passing object. The changes in the capacitance detected by the electrode 2 are transmitted back along the central conductor 21 as voltage signals and converted into distance measurements so that the distance between the electrode and the stationary or passing object can be calculated.

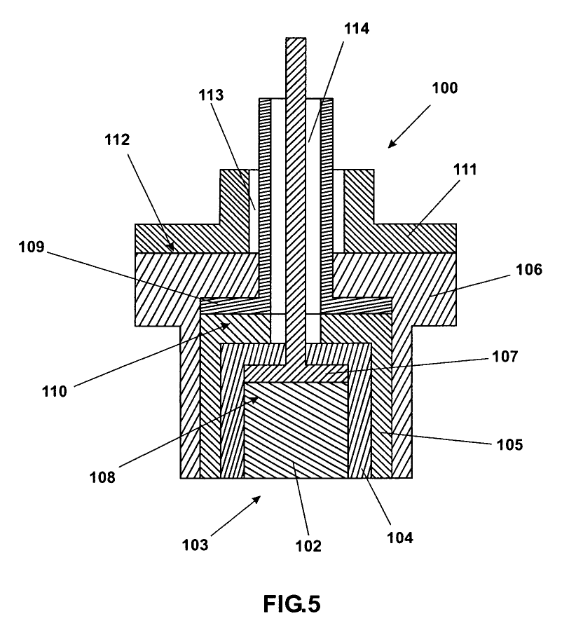

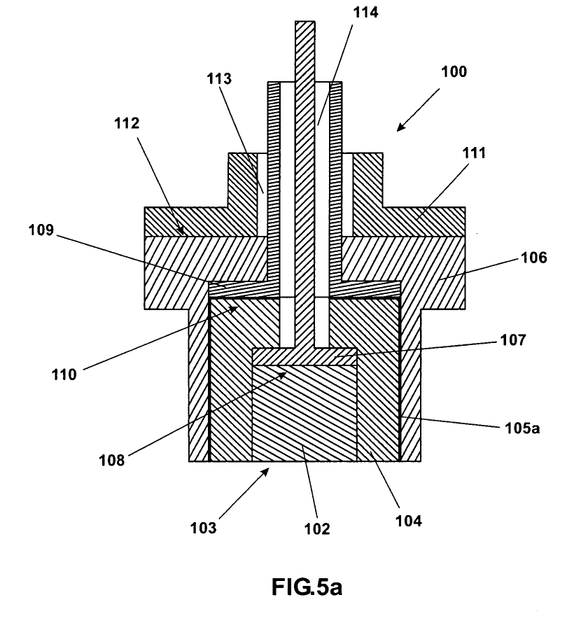

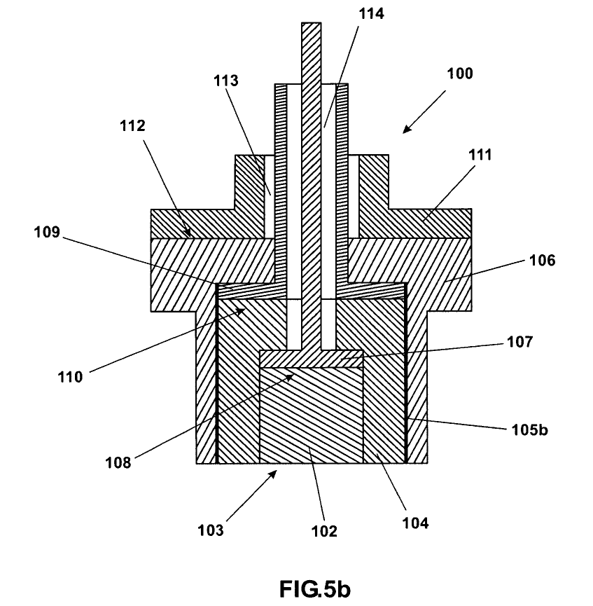

With reference to FIG. 5, a “triaxial” sensor 100 has a cylindrical electrode 102 formed from an electrically conductive ceramic material. A front face 103 of the electrode 102 is directed toward a stationary or passing object (not shown) . The electrode 102 is located within and bonded (e.g. diffusion bonded, sintered or brazed) to an electrically non-conductive ceramic spacer 104. The electrode 102 and the spacer 104 are located within and bonded to an electrically conductive ceramic shield 105 which isolates the electrode from any external electrical interference. The shield 105 is located within and bonded to a housing 106 formed from an electrically non-conductive ceramic material. The electrically conductive and electrically non-conductive ceramic materials are chosen so that they have a similar thermal expansion coefficient.

An inner bridge piece 107 is bonded to a rear face 108 of the electrode 102. An intermediate bridge piece 109 is bonded to a rear face 110 of the shield 105. An outer bridge piece 111 is bonded to a rear face 112 of the housing 106. The intermediate bridge piece 109 passes through apertures provided in the housing 106 and the outer bridge piece 111 to extend beyond the outer bridge piece. The inner bridge piece 107 passes through apertures provided in the spacer 104, the shield 105, the intermediate bridge piece 109 and the outer bridge piece 111 to extend beyond the intermediate bridge piece and the outer bridge piece. The aperture provided in the outer bridge piece 111 is wider than the intermediate bridge piece 109 so that the two bridge pieces are separated by an annular air gap 113. Similarly, the aperture provided in the intermediate bridge piece 109 is wider than the inner bridge piece 107 so that the two bridge pieces are separated by an annular air gap 114.

With reference to FIG. 5a, the electrically conductive ceramic shield 105 shown in FIG. 5 can be replaced by a thin electrically conductive ceramic layer 105a that is deposited onto the spacer 104 using conventional techniques. The ceramic layer 105a contacts the intermediate bridge piece and functions in exactly the same way as the shield 105. The use of a thin deposited ceramic layer 105a allows the size of the spacer 104 to be increased with an improvement in the strength and robustness of the sensor. The resulting sensor is also easier to assemble because to the simplification in the overall sensor design.

With reference to FIG. 5b, the electrically conductive ceramic shield 105 shown in FIG. 5 can be replaced by a thin electrically conductive ceramic or metallic layer 105b that is deposited onto the inside surface of the electrically non-conductive outer housing 106 using conventional deposition techniques. The conductive layer 105b contacts the intermediate bridge piece and functions in exactly the same way as the shield 105. The use of a thin deposited conductive layer 105b allows the size of the spacer to be increased with an improvement in the performance of the sensor. The sensor is also easier to assemble because of the simplification in the overall sensor design.

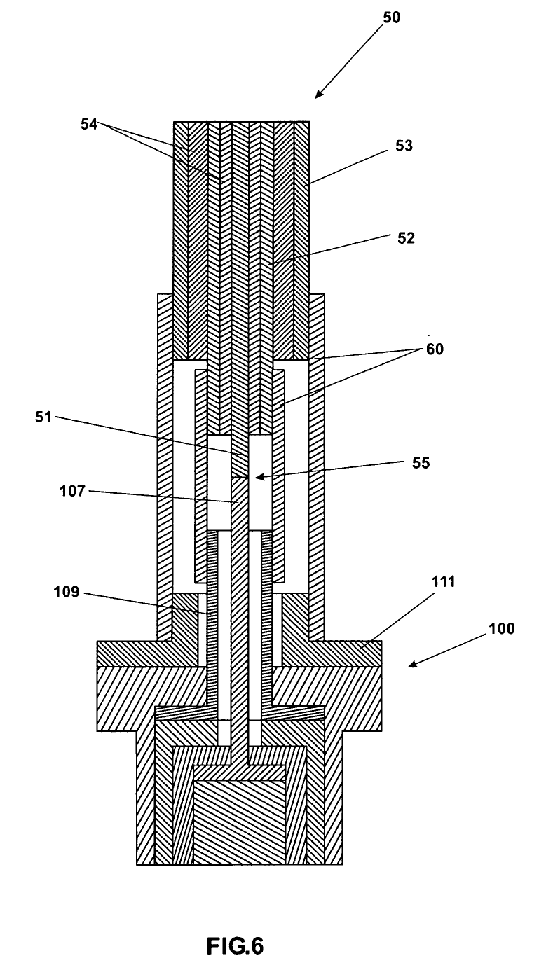

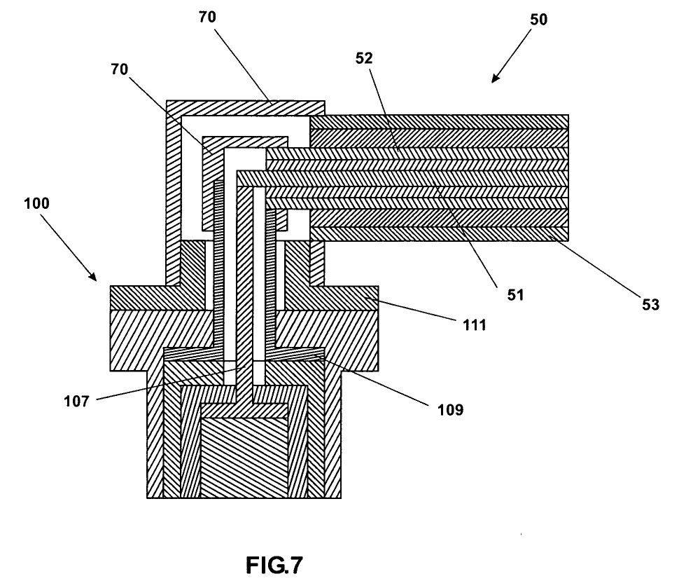

The inner, intermediate and outer bridge pieces 107, 109 and 111 are connected to the three concentric conductors of a mineral insulated triaxial transmission cable 50 as shown in FIG. 6. The transmission cable 50 has a central conductor 51, an intermediate conductor 52 and an outer conductor 53 separated by mineral insulating layers 54. An electrically conductive cylindrical adaptor 60 is used to join the inner bridge piece 107 to the central conductor 51 at a common interface 55, the intermediate bridge piece 109 to the intermediate conductor 52 and the outer bridge piece 111 to the outer conductor 53. Alternatively, the electrically conductive adaptor 70 shown in FIG. 7 can be used. The adaptor 70 is designed to receive the transmission cable 50 such that the central, intermediate and outer conductors 51, 52 and 53 are connected substantially at right angles to the inner, intermediate and outer bridge pieces 107, 109 and 111 and the centreline of the sensor 100.

The “triaxial” sensor 100 has the same technical advantages and may operate in the same way as the “coaxial” sensor 1 described above. It will be readily appreciated that different measurement electronics can be used with the “coaxial” and “triaxial” sensors.

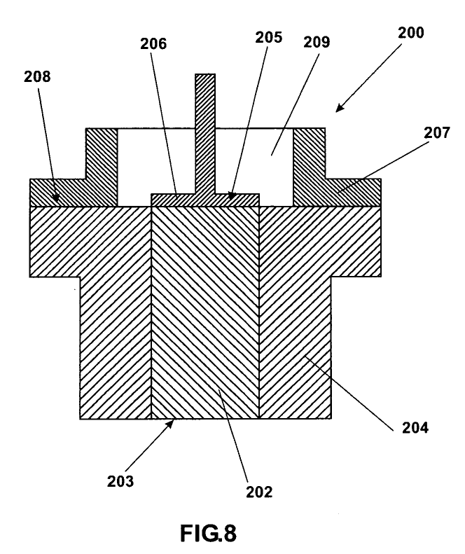

With reference to FIG. 8, an alternative “coaxial” sensor 200 has a cylindrical electrode 202 formed from an electrically conductive ceramic material. A front face 203 of the electrode 202 is directed toward a stationary or passing object (not shown). The electrode 202 is located within and bonded (e.g. diffusion bonded, sintered or brazed) to a housing 204 formed from an electrically non-conductive ceramic material. The electrode 202 extends the full depth of the housing 204 such that its rear face 205 is located at a low-temperature region of the sensor 200. The electrically conductive and electrically non-conductive ceramic materials are chosen so that they have a similar thermal expansion coefficient and the sensor 200 remains virtually stress free at high operating temperatures.

An inner bridge piece 206 is bonded to the rear face 205 of the electrode 202. An outer bridge piece 207 is bonded to a rear face 208 of the housing 204. The inner bridge piece 206 passes through an aperture provided in the outer bridge piece 207 to extend beyond the outer bridge piece. The aperture provided in the outer bridge piece 207 is wider than the inner bridge piece 206 so that the two bridge pieces are separated by an annular air gap 209.

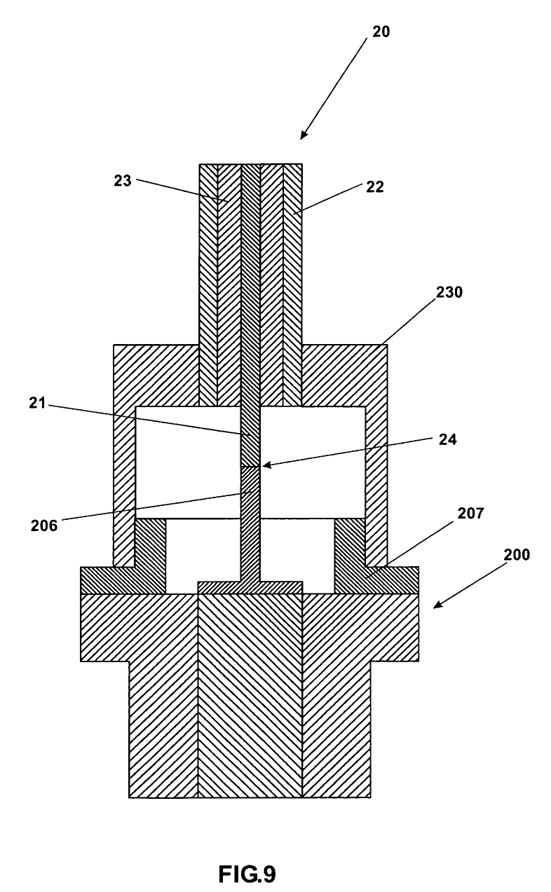

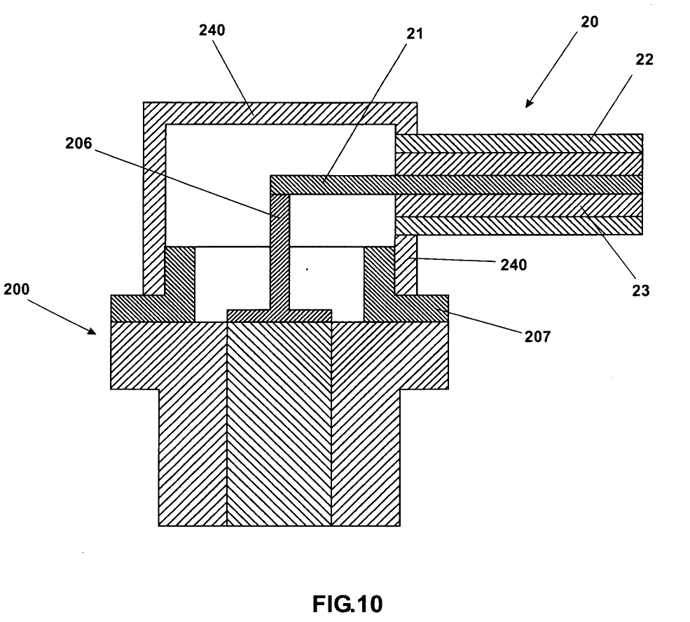

The inner and outer bridge pieces 206 and 207 are connected to the two concentric conductors of a mineral insulated coaxial transmission cable 20 as shown in FIG. 9. The transmission cable 20 has a central conductor 21 and an outer conductor 22 separated by a mineral insulating layer 23. An electrically conductive cylindrical adaptor 230 is used to join the inner bridge piece 206 to the central conductor 21 at a common interface 24 and the outer bridge piece 207 to the outer conductor 22. Alternatively, the electrically conductive adaptor 240 shown in FIG. 10 can be used. The adaptor 240 is designed to receive the transmission cable 20 such that central and outer conductors 21 and 22 are connected substantially at right angles to the inner and outer bridge pieces 206 and 207 and the centreline of the “coaxial” sensor 200.

It will be readily appreciated that the use of the adaptor 230, 240 means that the “coaxial” sensor 200 can be fully assembled and tested before being connected to the transmission cable 20. It also means that the inner and outer bridges pieces 206 and 207 and the central and outer conductors 21 and 22 are connected together at a low-temperature region or the sensor 200.

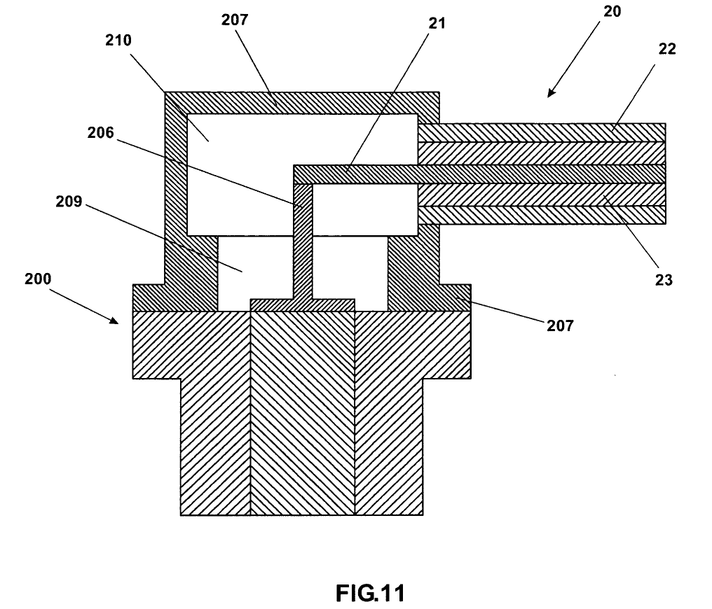

FIG. 11 shows how the central and outer conductors 21 and 22 of the transmission cable 20 can be connected to the inner and outer bridge pieces 206 and 207 without an adapter in such a way that the central and outer conductors 21 and 22 are connected substantially at right angles to the inner and outer bridge pieces 206 and 207 and the centreline of the “coaxial” sensor 200. In this case, the outer bridge piece 207 is shaped to extend into direct contact with the outer conductor 22 of the transmission cable 20. The inner bridge piece 206 is therefore spaced apart from the outer bridge piece 207 by an annular gap 209 and extends into a space 210 that is bounded by an extended part of the outer bridge piece which contacts the outer conductor 22 of the transmission cable 20.

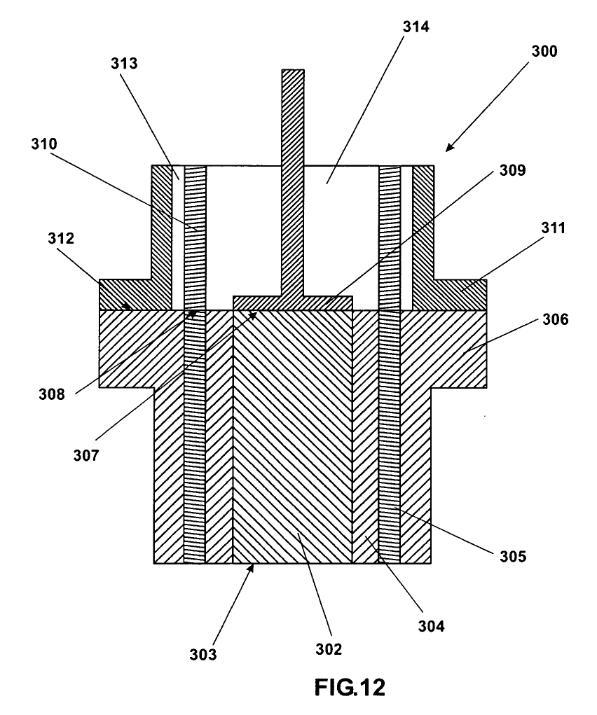

With reference to FIG. 12, an alternative “triaxial” sensor 300 has a cylindrical electrode 302 formed from an electrically conductive ceramic material. A front face 303 of the electrode 302 is directed toward a stationary or passing object (not shown). The electrode 302 is located within and bonded (e.g. diffusion bonded, sintered or brazed) to an electrically non-conductive ceramic spacer 304. The spacer 304 is located within and bonded to an electrically conductive ceramic shield 305 which isolates the electrode from any external electrical interference. The shield 305 is located within and bonded to a housing 306 formed from an electrically non-conductive ceramic material.

The electrode 302 and shield 305 extend the full depth of the housing 306 such that their rear faces 307 and 308, respectively, are located at a low-temperature region of the sensor 300. The electrically conductive and electrically non-conductive ceramic materials are chosen so that they have a similar thermal expansion coefficient.

An inner bridge piece 309 is bonded to the rear face 307 of the electrode 302. An intermediate bridge piece 310 is bonded to the rear face 308 of the shield 305. An outer bridge piece 311 is bonded to a rear face 312 of the housing 306. The intermediate bridge piece 310 passes through an aperture provided in the outer bridge piece 311. The inner bridge piece 309 passes through apertures provided in the intermediate bridge piece 310 and the outer bridge piece 311 to extend beyond the intermediate bridge piece and the outer bridge piece. The aperture provided in the outer bridge piece 311 is wider than the intermediate bridge piece 310 so that the two bridge pieces are separated by an annular air gap 313. Similarly, the aperture provided in the intermediate bridge piece 310 is wider than the inner bridge piece 309 so that the two bridge pieces are separated by an annular air gap 314.

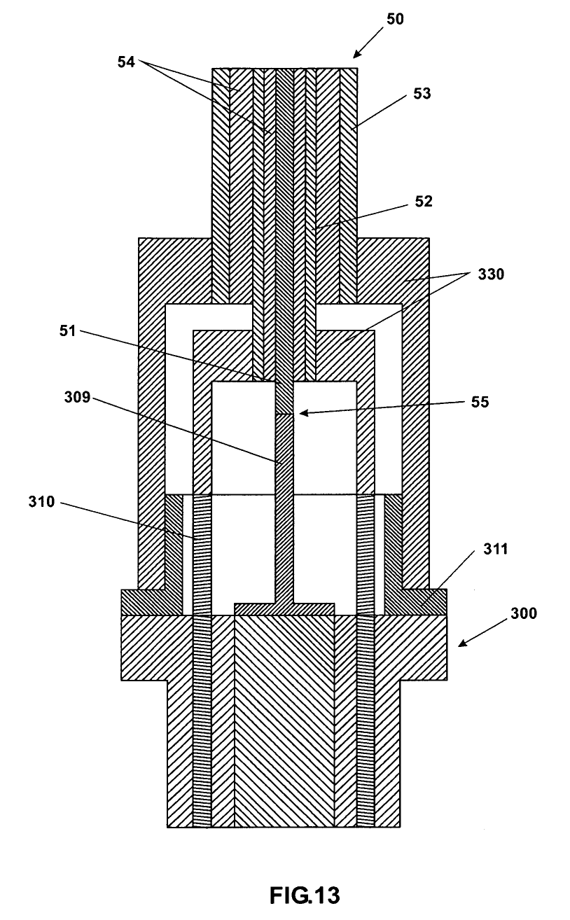

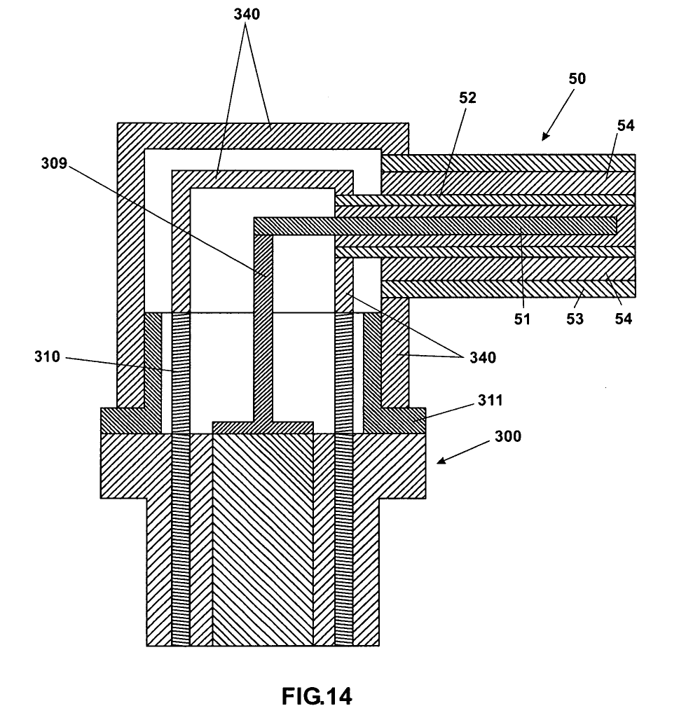

The inner, intermediate and outer bridge pieces 309, 310 and 311 are connected to the three concentric conductors of a mineral insulated triaxial transmission cable 50 as shown in FIG. 13. The transmission cable 50 has a central conductor 51, an intermediate conductor 52 and an outer conductor 53 separated by mineral insulating layers 54. An electrically conductive cylindrical adaptor 330 is used to join the inner bridge piece 309 to the central conductor 51 at a common interface 55, the intermediate bridge piece 310 to the intermediate conductor 52 and the outer bridge piece 311 to the outer conductor 53. Alternatively, the electrically conductive adaptor 340 shown in FIG. 14 can be used. The adaptor 340 is designed to receive the transmission cable 50 such that the central, intermediate and outer conductors 51, 52 and 53 are connected substantially at right angles to the inner, intermediate and outer bridge pieces 309, 310 and 311 and the centreline of the sensor 300.

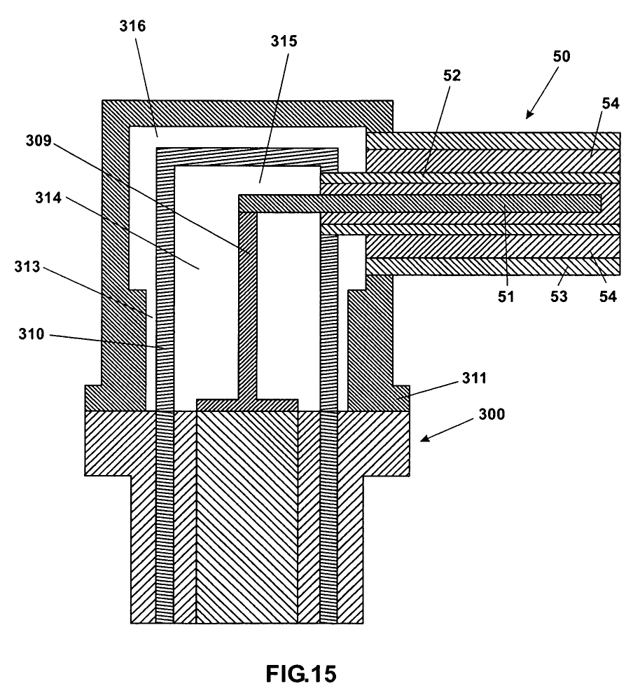

FIG. 15 shows how the central, intermediate and outer conductors 51, 52 and 53 of the transmission cable 50 can be connected to the inner, intermediate and outer bridge pieces 309, 310 and 311 without an adapter in such a way that the central, intermediate and outer conductors 51, 52 and 53 are connected substantially at right angles to the inner, intermediate and outer bridge pieces and the centreline of the “coaxial” sensor 300. In this case, the outer bridge piece 311 is shaped to extend into direct contact with the outer conductor 53 of the transmission cable 50 and the intermediate bridge piece 310 is shaped to extend into direct contact with the intermediate conductor 52 of the transmission cable. The inner bridge piece 309 is therefore spaced apart from the intermediate bridge piece 310 by an annular gap 314 and extends into a space 315 that is bounded by an extended part of the intermediate bridge piece which contacts the intermediate conductor 52 of the transmission cable 50. Similarly, the intermediate bridge piece 310 is spaced apart from the outer bridge piece 311 by an annular gap 313 and extends into a space 316 that is bounded by an extended part of the outer bridge piece which contacts the outer conductor 53 of the transmission cable 50.

The “coaxial” sensor 200 and the “triaxial” sensor 300 have the same technical advantages and may operate in the same way as the “coaxial” sensor 1 described above. It will be readily appreciated that different measurement electronics can be used with the “coaxial” and “triaxial” sensors.

Although all of the sensors described above have electrodes made of electrically conductive ceramic, it will be readily appreciated that the electrodes may also be made of other electrically conductive materials such as metal or a mixture of metal and ceramic, or include an electrically conductive outer layer or coating. The method of bonding the electrode to the surrounding housing (in the case of a “coaxial” sensor) or the surrounding shield (in the case of a “triaxial” sensor) will be chosen according to the electrode material.

Although all of the sensors described above have cylindrical electrodes, it will be readily appreciated that different electrode shapes may be chosen according to the measurement application. For sensors with cylindrical electrodes, it is common practice to produce cylindrical shields, however different electrode shapes may also necessitate different shield shapes, which are also chosen to suit the measurement application.

All the various bridge pieces may be made of any electrically conductive material such as metal or electrically conductive ceramic metal. The method of bonding the bridge pieces to the electrode, shield and housing will be chosen according to the bridge piece material.

Although all of the sensors described above are shown with transmission cables having a single concentric central conductor it will be readily appreciated that transmission cables with one or more central conductors may also be used, to suit the measurement application and type of electronics used.

1. A sensor comprising: an electrode for capacitively coupling with the object, a housing that substantially surrounds the electrode, a first electrically conductive bridge connected to the electrode and connectable to a first conductor of a transmission cable, and a second electrically conductive bridge connected to the housing and connectable to a second conductor of the transmission cable.

2. A sensor according to claim 1, wherein the housing is formed from an electrically non-conductive ceramic.

3. A sensor according to claim 1, further comprising a shield that surrounds the electrode and is electrically isolated from the electrode by an insulating layer.

4. A sensor according to claim 3, wherein the shield is formed from a solid piece of electrically conductive ceramic.

5. A sensor according to claim 3, wherein the shield is a deposited electrically conductive ceramic layer.

6. A sensor according to claim 3, wherein the shield is a deposited electrically conductive ceramic or metal layer.

7. A sensor according to claim 3, wherein the insulating layer is formed from an electrically non-conductive ceramic.

8. A sensor according to claim 1, wherein the first electrically conductive bridge passes through apertures provided in the housing and the second electrically conductive bridge.

9. A sensor according to claim 1, wherein the second electrically conductive bridge substantially surrounds the housing.

10. A sensor according to claim 1, further comprising an adaptor for connecting the second electrically conductive bridge to the second conductor of the transmission cable.

11. A sensor according to claim 3, further comprising a third electrically conductive bridge connected to the shield and connectable to a third conductor of the transmission cable.

12. A sensor according to claim 11, wherein the first electrically conductive bridge passes through apertures provided in the insulating layer, the shield, the third electrically conductive bridge, the housing and the second electrically conductive bridge, and wherein the third electrically conductive bridge passes through apertures provided in the housing and the second electrically conductive bridge.

13. A sensor according to claim 11, further comprising an adaptor for connecting the second electrically conductive bridge to the second conductor of the transmission cable and the third electrically conductive bridge to the third conductor of the transmission cable.

14. A sensor according to claim 3, wherein one or more of the electrode, shield, insulating layer and housing are bonded together.

15. A sensor according to claim 14, wherein the bonding provides a hermetic seal between the one or more of the electrode, shield, insulating layer and housing.

16. A sensor according to claim 1, wherein the electrode is formed from an electrically conductive ceramic.

17. A sensor according to claim 1, wherein the first electrically conductive bridge extends into an aperture provided in the second electrically conductive bridge.

18. A sensor according to claim 11, wherein the first electrically conductive bridge extends into an aperture provided in the third electrically conductive bridge, and wherein the third electrically conductive bridge extends into an aperture provided in the second electrically conductive bridge.
